(19) United States
(12) Patent Application Publication
(10) Pub. No.: US 2024/0276827 A1
(43) Pub. Date: Aug. 15, 2024

(54) DISPLAY DEVICE

(71) Applicant: Samsung Display Co., Ltd., Yongin-si (KR)

(72) Inventors: MOON-KEUN CHOI, Yongin-si (KR); HYUNBAE PARK, Yongin-si (KR); SEUNGHUI SEO, Yongin-si (KR); Hyelynn SONG, Yongin-si (KR); TAE WOO LIM, Yongin-si (KR)

(73) Assignee: Samsung Display Co., Ltd., Yongin-si (KR)

(21) Appl. No.: 18/539,529

(22) Filed: Dec. 14, 2023

(30) Foreign Application Priority Data
Feb. 14, 2023 (KR) 10-2023-0019199

(51) Int. Cl. H10K 59/38; H10K 59/122; H10K 59/80

(52) U.S. Cl. CPC H10K 59/38; H10K 59/122; H10K 59/873

(57) ABSTRACT

A display device includes a base layer having a plurality of light-emitting regions and a non-light-emitting region disposed adjacent to the plurality of light-emitting regions, and a color filter layer disposed on the base layer. The color filter layer includes a first color filter that transmits a first color light, a second color filter that transmits a second color light, the first color light and the second color light being different from each color, and a third color filter that transmits a third color light, the first color light, the second color light, and the third color light being different from each other. The first to third color filters overlap each other in the non-light-emitting region in a plan view, and in the third color filter, a measurement opening is defined in a region overlapping the non-light-emitting region in a plan view.

### CROSS REFERENCE TO RELATED APPLICATION(S)

This application claims priority to and benefits of Korean Patent Application No. 10-2023-0019199 under 35 U.S.C. § 119, filed on Feb. 14, 2023, in the Korean Intellectual Property Office (KIPO), the entire contents of which are incorporated herein by reference.

### BACKGROUND

### 1. Technical Field

The disclosure relates to a display device having improved measurement reliability by using a measurement opening included in a color filter.

### 2. Description of the Related Art

A display panel includes a transmissive display panel which selectively transmits source light generated from a light source and a light-emitting display panel which generates source light. The display panel may include different types of light control patterns depending on pixels in order to generate a color image. The light control pattern may transmit only a portion of the wavelength range of the source light or convert a color of the source light. Some of the light control patterns may change the characteristics of light without changing the color of the source light.

### SUMMARY

The disclosure provides a display device having improved measurement reliability by using a measurement opening included in a color filter.

According to an embodiment of the disclosure, a display device may include a base layer having a plurality of light-emitting regions and a non-light-emitting region disposed adjacent to the plurality of light-emitting regions, and a color filter layer disposed on the base layer. The color filter layer may include a first color filter that transmits a first color light, a second color filter that transmits a second color light, the first color light and the second color light being different from each other, and a third color filter that transmits a third color light, the first color light, the second color light, and the third color light being different from each other. The first to third color filters may overlap each other in the non-light-emitting region in a plan view, and in the third color filter, a measurement opening may be defined in a region overlapping the non-light-emitting region in a plan view.

In an embodiment, the plurality of light-emitting regions may include a first light-emitting region overlapping a portion of the first color filter in a plan view, a second light-emitting region overlapping a portion of the second color filter in a plan view, and a third light-emitting region overlapping a portion of the third color filter in a plan view.

In an embodiment, a size of the measurement opening may be smaller than a size of each of the first to third light-emitting regions in a plan view.

In an embodiment, the first color light may be blue light, the second color light may be red light, and the third color light may be green light.

In an embodiment, the measurement opening may overlap the first color filter and the second color filter in a plan view.

In an embodiment, the measurement opening may have a polygonal shape in a plan view.

In an embodiment, the display device may further include a lower display substrate including a first base substrate, a plurality of light-emitting elements disposed on the first base substrate, and a thin film encapsulation layer that covers the plurality of light-emitting elements.

In an embodiment, the display device may further include a partition barrier rib disposed on the color filter layer and having a plurality of partition openings overlapping the plurality of light-emitting regions in a plan view, and a plurality of optical patterns disposed in the plurality of partition openings. An upper surface of the partition barrier rib may face an upper surface of the lower display substrate.

In an embodiment, the display device may further include a plurality of light-emitting elements disposed on the base layer, a thin film encapsulation layer that covers the plurality of light-emitting elements, a partition barrier rib disposed on the thin film encapsulation layer and having a plurality of partition openings overlapping the plurality of light-emitting regions in a plan view, and a plurality of optical patterns disposed in the plurality of partition openings. The first to third color filters may be disposed on the partition barrier rib and the plurality of optical patterns.

In an embodiment, a plurality of first openings may be defined in the first color filter, and each of the plurality of first openings may overlap at least one of the second color filter and the third color filter in a plan view.

In an embodiment, a plurality of second openings may be defined in the second color filter, and each of the plurality of second openings may overlap at least one of the first color filter and the third color filter in a plan view.

In an embodiment, a plurality of third openings may be further defined in the third color filter, and each of the plurality of third openings may overlap at least one of the first color filter and the second color filter in a plan view.

In an embodiment of the disclosure, a display device may include a base layer, a first color filter disposed on the base layer and having a plurality of first openings, a second color filter disposed on the base layer and having a plurality of second openings, and a third color filter disposed on the base layer and having a plurality of third openings and a measurement opening. Each of the plurality of first openings may overlap at least one of the second color filter and the third color filter in a plan view, each of the plurality of second openings may overlap at least one of the first color filter and the third color filter in a plan view, each of the plurality of third openings may overlap at least one of the first color filter and the second color filter in a plan view, and the measurement opening may overlap the first color filter and the second color filter in a plan view.

In an embodiment, a plurality of light-emitting regions and a non-light-emitting region disposed adjacent to the plurality of light-emitting regions may be defined in the base layer, and the measurement opening may overlap the non-light-emitting region in a plan view.

In an embodiment, a size of the measurement opening may be smaller than a size of each of the plurality of light-emitting regions in a plan view.

In an embodiment, the first color filter may transmit blue light, the second color filter may transmit red light, and the third color filter may transmit green light.

In an embodiment, the measurement opening may have a polygonal shape in a plan view.

In an embodiment, the display device may further include a lower display substrate including a first base substrate, a plurality of light-emitting elements disposed on the first base substrate, and a thin film encapsulation layer that covers the plurality of light-emitting elements.

In an embodiment, the display device may further include a partition barrier rib disposed on the first to third color filters and having a plurality of partition openings overlapping the plurality of light-emitting regions in a plan view, and a plurality of optical patterns disposed in the plurality of partition openings. An upper surface of the partition barrier rib may face an upper surface of the lower display substrate.

In an embodiment, the display device may further include a base substrate, a plurality of light-emitting elements disposed on the base substrate, a thin film encapsulation layer that covers the plurality of light-emitting elements, a partition barrier rib disposed on the thin film encapsulation layer and having a plurality of partition openings overlapping the plurality of light-emitting regions in a plan view, and a plurality of optical patterns disposed in the plurality of partition openings. The first to third color filters may be disposed on the partition barrier rib and the plurality of optical patterns.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain principles of the disclosure. In the drawings:

FIG. 1A is a schematic perspective view of a display device according to an embodiment of the disclosure;

FIG. 1B is a schematic cross-sectional view illustrating components of a display panel according to an embodiment of the disclosure;

FIG. 2 is a schematic enlarged plan view illustrating a portion of a display area of the display panel according to an embodiment of the disclosure;

FIG. 3 is a schematic cross-sectional view of the display panel according to an embodiment of the disclosure;

FIG. 4 is a schematic enlarged plan view illustrating a portion of a display area of the display panel according to an embodiment of the disclosure; and

FIG. 5 is a schematic cross-sectional view of a display panel according to an embodiment of the disclosure.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

The terminology used herein is for the purpose of describing particular embodiments and is not intended to be limiting. As used herein, the singular forms, “a,” “an,” and “the” are intended to include the plural forms as well, unless the context clearly indicates otherwise. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

In this specification, it will be understood that when an element (or region, area, layer, portion, substrate, etc.) is referred to as being “on” or “connected to” another element, it can be directly on or connected to the other element, or intervening elements may be present. When, however, an element or layer is referred to as being “directly on” or “ directly connected to” another element or layer, there are no intervening elements or layers present. To this end, the term “connected” may refer to physical, electrical, and/or fluid connection, with or without intervening elements. Further, the first direction DR1, the second direction DR2, and the third direction DR3 are not limited to three axes of a rectangular coordinate system, such as the x, y, and z axes, and may be interpreted in a broader sense. For example, the first direction DR1, the second direction DR2, and the third direction DR3 may be perpendicular to one another, or may represent different directions that are not perpendicular to one another.

When a component is described herein to “connect” another component to the other component or to be “connected to” other components, the components may be connected to each other as separate elements, or the components may be integral with each other.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some example embodiments may be physically separated into two or more interacting and discrete blocks, units, and/or modules without departing from the scope of the disclosure. Further, the blocks, units, and/or modules of some example embodiments may be physically combined into more complex blocks, units, and/or modules without departing from the scope of the disclosure.

Like reference numerals refer to like elements throughout. In addition, in the drawings, the thicknesses, ratios, and dimensions of elements are exaggerated for effective description of the technical contents. As used herein, the term “and/or” includes any and all combinations that the associated configurations can define. For example, “A and/or B” may be understood to mean “A, B, or A and B.” The terms “and” and “or” may be used in the conjunctive or disjunctive sense and may be understood to be equivalent to “and/or.” For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

It will be understood that, although the terms “first,” “second,” etc. may be used herein to describe various elements, these elements should not be limited by these terms. These terms are only used to distinguish one element from another element. For example, a first element could be termed a second element without departing from the scope of the disclosure. Similarly, the second element may also be referred to as the first element. The terms of a singular form include plural forms unless otherwise specified.

In addition, terms, such as “below”, “lower”, “above”, “upper” and the like, are used herein for ease of description to describe one element's relation to another element(s) as illustrated in the figures. The above terms are relative concepts and are described based on the directions indicated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the example term “below” can encompass both an orientation of above and below. Furthermore, the apparatus may be otherwise oriented (e.g., rotated 90 degrees or at other orientations), and, as such, the spatially relative descriptors used herein interpreted accordingly.

It will be understood that the terms “comprise,” “include,” and/or “have”, when used in this specification, specify the presence of stated features, integers, steps, operations, elements, components and/or combinations thereof, but do not preclude the presence or addition of one or more other features, integers, steps, operations, elements, components, and/or combinations thereof.

Unless otherwise specified, the illustrated embodiments are to be understood as providing example features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Hereinafter, a front surface (or a top surface) and a rear surface (or a bottom surface) of each of layers or units may be distinguished by the third direction DR3. However, directions indicated by the first to third directions DR1, DR2, and DR3 may be a relative concept, and converted with respect to each other, e.g., converted into opposite directions.

The display surface may be parallel to a surface defined by a first direction DR1 and a second direction DR2. A normal direction of the display surface, i.e., a thickness direction of the display device DD, may indicate a third direction DR3. In this specification, an expression of “when viewed from the top or in a plan view” may represent a case when viewed in the third direction DR3. Hereinafter, a front surface (or a top surface) and a rear surface (or a bottom surface) of each of layers or units may be distinguished by the third direction DR3. However, directions indicated by the first to third directions DR1, DR2, and DR3 may be a relative concept, and converted with respect to each other, e.g., converted into opposite directions.

Unless otherwise defined or implied, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the disclosure will be described with reference to the accompanying drawings.

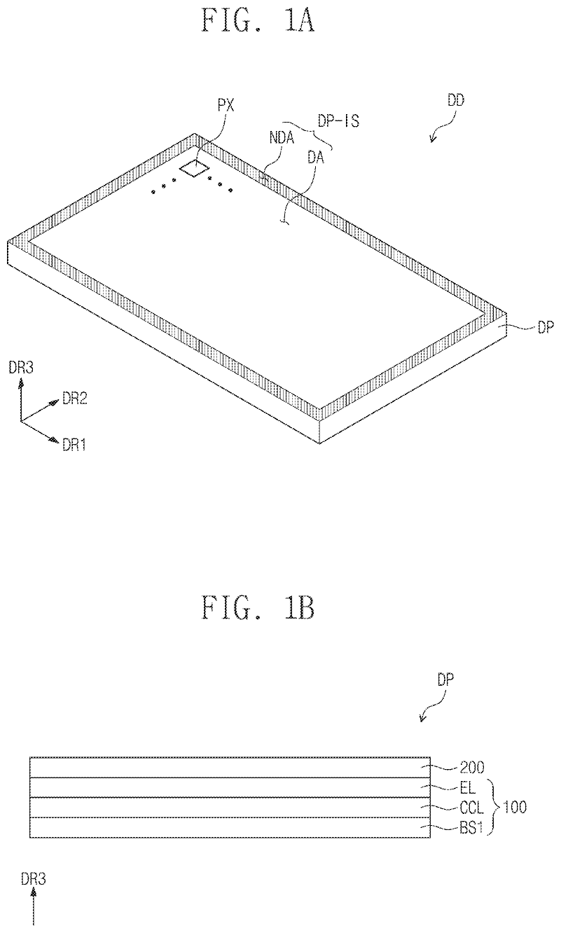

FIG. 1A is a schematic perspective view of a display device DD according to an embodiment of the disclosure. As illustrated in FIG. 1A, the display device DD may display an image through a display surface DP-IS. The display surface DP-IS may be parallel to a plane defined by a first direction DR1 and a second direction DR2 intersecting the first direction DR1. The display surface DP-IS may include a display area DA and a non-display area NDA. A pixel PX may be disposed in the display area DA and may be not disposed in the non-display area NDA. The non-display area NDA may be a portion of an edge of the display surface DP-IS. The non-display area NDA may be disposed adjacent to the display area DA. For example, the non-display area NDA may be defined along the edge of the display surface DP-IS. For example, the non-display area NDA may surround the display area DA. However, the display area DA and the non-display area NDA illustrated in FIG. 1A are embodiments, and the disclosure is not limited thereto. For example, the non-display area NDA may be omitted or disposed only on a side of the display area DA.

A third direction DR3 may be a normal direction of the display surface DP-IS, for example, a thickness direction of the display device DD. The third direction DR3 may intersect the first direction DR1 and the second direction DR2. A front surface (or an upper surface) and a rear surface (or a lower surface) of each of layers or components described below may be defined by the third direction DR3. However, the first to third directions DR1, DR2, and DR3 illustrated in the drawings are not limited thereto.

In an embodiment of the disclosure, the display device DD is illustrated as having a flat display surface DP-IS, but the disclosure is not limited thereto. The display device DD may include a curved display surface, a three-dimensional display surface, the like, or a combination thereof. The three-dimensional display surface may include multiple display areas facing different directions.

The display device DD may include a display panel DP. Although not separately illustrated, the display device DD according to an embodiment of the disclosure may further include a protective member disposed on a lower surface of the display panel DP, an input sensor, an anti-reflection member, a window member, or the like disposed on an upper surface of the display panel DP.

For example, the display panel DP may be a light-emitting display panel. However, the disclosure is not particularly limited thereto. For example, the display panel DP may be an organic light-emitting display panel, an inorganic light-emitting display panel, or the like. A light-emitting layer in the organic light-emitting display panel may include an organic light-emitting material. A light-emitting layer in the inorganic light-emitting display panel may include quantum dots, quantum rods, micro LEDs, the like, or a combination thereof. Hereinafter, the display panel DP will be described as an organic light-emitting display panel.

FIG. 1B is a schematic cross-sectional view illustrating components of a display panel DP according to an embodiment of the disclosure.

Referring to FIG. 1B, the display panel DP may include a lower display substrate 100 and an upper display substrate 200. The lower display substrate 100 may include a first base substrate BS1, a circuit layer CCL, and a display element layer EL.

The first base substrate BS1 may be a synthetic resin substrate, a glass substrate, the like, or a combination thereof.

The circuit layer CCL may be disposed on the first base substrate BS1. The circuit layer CCL may include at least one insulating layer and a circuit element. The circuit element may include a signal line, a pixel driving circuit, the like, or a combination thereof. The circuit layer CCL may be formed through a process of forming an insulating layer, a semiconductor layer, and a conductive layer by coating, deposition, or the like and through a process of patterning the insulating layer, the semiconductor layer, and the conductive layer by a photolithography method or the like.

The display element layer EL may be disposed on the circuit layer CCL. The display element layer EL may include multiple light-emitting elements. The lower display substrate 100 may further include an encapsulation layer covering the light-emitting elements. Details will be described below.

The upper display substrate 200 may change the color of light provided from the light-emitting elements. The upper display substrate 200 may include a light control pattern and a structure that increases light conversion efficiency.

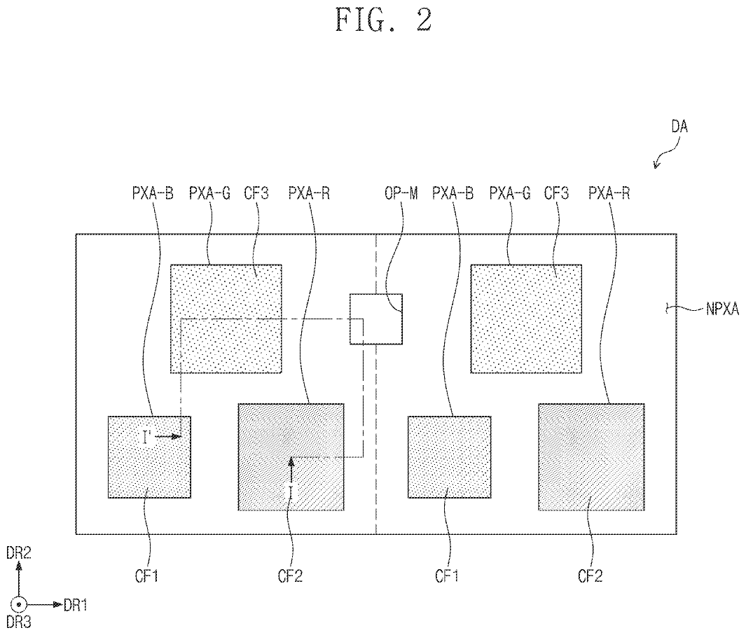

FIG. 2 is a schematic enlarged plan view illustrating a portion of the display area DA of the display panel DP (see, e.g., FIG. 1A) according to an embodiment of the disclosure. FIG. 2 schematically illustrates a portion of the display panel DP viewed from above the display surface DP-IS (e.g., the display area DA), and schematically illustrates an arrangement of multiple light-emitting regions PXA-B, PXA-R, and PXA-G.

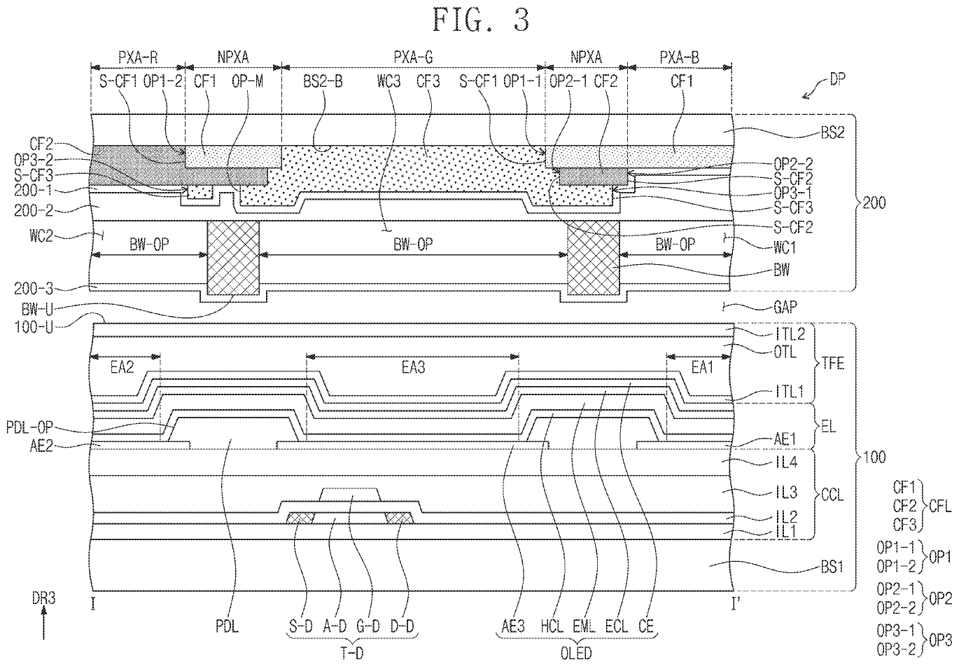

Referring to FIG. 2, the display area DA may include multiple light-emitting regions PXA-B, PXA-R, and PXA-G and a non-light-emitting region NPXA surrounding the light-emitting regions PXA-B, PXA-R, and PXA-G. The light-emitting regions PXA-B, PXA-R, and PXA-G may include a first light-emitting region PXA-B overlapping a portion of a first color filter CF1 in a plan view, a second light-emitting region PXA-R overlapping a second color filter CF2 in a plan view, and a third light-emitting region PXA-G overlapping a portion of a third color filter CF3 in a plan view. The first to third light-emitting regions PXA-B, PXA-R, and PXA-G may each correspond to regions in which light is emitted from light-emitting elements OLED (see, e.g., FIG. 3). The first to third light-emitting regions PXA-B, PXA-R, and PXA-G may be classified according to color (e.g., blue color, red color, green color) of light emitted toward an outside of the display panel DP (see, e.g., FIG. 1A).

The first to third light-emitting regions PXA-B, PXA-R, and PXA-G may provide first to third color lights having different colors. For example, a first color light may be blue light, a second color light may be red light, and a third color light may be green light. However, the first to third color lights are not necessarily limited thereto.

The first to third light-emitting regions PXA-B, PXA-R, and PXA-G may be respectively regions in which the first to third color filters CF1, CF2, and CF3 are exposed by multiple first to third openings OP1, OP2, and OP3 (see, e.g., FIG. 3) of the first to third color filters CF1, CF2, and CF3 to be described below.

The non-light-emitting region NPXA may set boundaries of the first to third light-emitting regions PXA-B, PXA-R, and PXA-G and may prevent color mixing between the first light-emitting region PXA-B, the second light-emitting region PXA-R, and the third light-emitting region PXA-G. The non-light-emitting region NPXA may block source light so that the source light may not be provided to a user.

The display area DA may include multiple first to third light-emitting regions PXA-B, PXA-R, and PXA-G, and the first to third light-emitting regions PXA-B, PXA-R, and PXA-G may be repeatedly arranged in a pattern (e.g., a predetermined or selectable pattern) in the display area DA. For example, the first and second light-emitting regions PXA-B and PXA-R may be alternately arranged in the first direction DR1 to form a ‘first group’, and the third light-emitting regions PXA-G may be arranged in the first direction DR1 to form a ‘second group’. The display area DA may include multiple first groups and multiple second groups, and the ‘first groups’ and the ‘second groups’ may be alternately arranged in the second direction DR2. FIG. 2 schematically illustrates only two first to third light-emitting regions PXA-B, PXA-R, and PXA-G.

FIG. 2 illustrates an arrangement of the first to third light-emitting regions PXA-B, PXA-R, and PXA-G, but the disclosure is not limited thereto, and the first to third light-emitting regions PXA-B, PXA-R, and PXA-G may be arranged in various forms. In an embodiment of the disclosure, the first to third light-emitting regions PXA-B, PXA-R, and PXA-G may have a PenTile™ arrangement form as illustrated in FIG. 2. In another embodiment, the first to third light-emitting regions PXA-B, PXA-R, and PXA-G may have a stripe arrangement form, a Diamond Pixel™ arrangement form, the like, or a combination thereof.

The first to third light-emitting regions PXA-B, PXA-R, and PXA-G may have various shapes in a plan view. For example, the first to third light-emitting regions PXA-B, PXA-R, and PXA-G may have polygonal, circular, elliptical shapes, the like, or a combination thereof. FIG. 2 illustrates the first to third light-emitting regions PXA-B, PXA-R, and PXA-G having a tetragonal shape (or a rhombic shape) in a plan view.

At least some of the first to third light-emitting regions PXA-B, PXA-R, and PXA-G may have different areas in a plan view. In an embodiment of the disclosure, an area of the first light-emitting region PXA-B that emits blue light may be smaller than an area of the second light-emitting region PXA-R that emits red light and an area of the third light-emitting region PXA-G that emits green light. However, a size relationship of the areas between the first light-emitting region PXA-B, the second light-emitting region PXA-R, and the third light-emitting region PXA-G according to the light-emitting colors is not limited thereto. The size relationship of the areas between the first light-emitting region PXA-B, the second light-emitting region PXA-R, and third light-emitting region PXA-G according to the light-emitting colors may vary according to a design of a display module. Without being limited thereto, the first to third light-emitting regions PXA-B, PXA-R, and PXA-G may have a same area in a plan view.

A shape, an area, an arrangement, and/or the like of the first to third light-emitting regions PXA-B, PXA-R, and PXA-G according to the disclosure may be designed in various ways according to a color of emitted light, a size and a configuration of the display module, or the like, and are not limited to the embodiment illustrated in FIG. 2.

FIG. 3 is a schematic cross-sectional view of the display panel DP according to an embodiment of the disclosure.

Referring to FIG. 3, the display panel DP may include a lower display substrate 100 and an upper display substrate 200 which faces and is spaced apart from the lower display substrate 100 in the third direction DR3. A cell gap GAP (e.g., a predetermined or selectable cell gap GAP) may be formed between the lower display substrate 100 and the upper display substrate 200. The cell gap GAP may be maintained by a sealant (not illustrated) that bonds the lower display substrate 100 and the upper display substrate 200 to each other. The sealant may be disposed in the non-display area NDA illustrated in FIG. 1A. In an embodiment of the disclosure, a synthetic resin material or the like may be disposed in the cell gap GAP. FIG. 3 illustrates an embodiment that the display panel DP is an organic light-emitting display panel.

A first light-emitting region PXA-B, a second light-emitting region PXA-R, a third light-emitting region PXA-G, and a non-light-emitting region NPXA may be disposed in the display panel DP.

The lower display substrate 100 may include a first base substrate BS1, a circuit layer CCL, a display element layer EL, and a thin film encapsulation layer TFE.

The first base substrate BS1 may have a stacked structure of a silicon substrate, a plastic substrate, a glass substrate, an insulating film, the like, or multiple insulating layers.

The circuit layer CCL may be disposed on the first base substrate BS1. The circuit layer CCL may include multiple insulating layers IL1, IL2, IL3, and IL4, multiple conductive layers, and a semiconductor layer. FIG. 3 illustrates one driving transistor T-D. The insulating layers IL1, IL2, IL3, and IL4 may include a first insulating layer IL1, a second insulating layer IL2, a third insulating layer IL3, and a fourth insulating layer IL4.

The first insulating layer IL1 may be disposed on the first base substrate BS1, and the driving transistor T-D may be disposed on the first insulating layer IL1. The first insulating layer IL1 may be a barrier layer that protects lower surfaces of an active A-D, a source S-D, and a drain D-D, and the first insulating layer IL1 may block pollutants, moisture, and/or the like from entering the active A-D, the source S-D, and the drain D-D from or through the first base substrate BS1. In another embodiment, the first insulating layer IL1 may be a light blocking layer that blocks external light incident through the first base substrate BS1 from being incident to the active A-D, and the first insulating layer IL1 may further include a light blocking material.

The driving transistor T-D may include the active A-D, the source S-D, the drain D-D, and a gate G-D. The active A-D, the source S-D, and the drain D-D may be regions classified according to a doping concentration or a conductivity of a semiconductor pattern. The active A-D, the source S-D, and the drain D-D may be disposed on the first insulating layer IL1. The active A-D, the source S-D, and the drain D-D may have higher adhesion to the first insulating layer IL1 than to the first base substrate BS1.

The second insulating layer IL2 may be disposed on the first insulating layer IL1 and cover the active A-D, the source S-D, and the drain D-D. The second insulating layer IL2 may include an inorganic material. For example, the second insulating layer IL2 may include at least one of silicon nitride, silicon oxynitride, silicon oxide, titanium oxide, and aluminum oxide.

The gate G-D may be disposed on the second insulating layer IL2. The third insulating layer IL3 may be disposed on the second insulating layer IL2 and cover the gate G-D. The third insulating layer IL3 may have a single layer or multiple layers. For example, the third insulating layer IL3 may include an inorganic layer or the like. For example, the third insulating layer IL3 may include an organic layer, an inorganic layer, and the like.

The fourth insulating layer IL4 may be disposed on the third insulating layer IL3. The fourth insulating layer IL4 may have a single layer or multiple layers. For example, the fourth insulating layer IL4 may include an organic layer or the like. For example, the fourth insulating layer IL4 may include an organic layer, an inorganic layer, and the like. The fourth insulating layer IL4 may be a planarization layer that provides a flat surface on an upper surface of the fourth insulating layer IL4 (e.g., the planarization layer).

The display element layer EL may be disposed on the circuit layer CCL. The display element layer EL may be disposed on the fourth insulating layer IL4. The display element layer EL may include a light-emitting element OLED and a pixel defining film PDL. In an embodiment, the light-emitting element OLED may be an organic light-emitting diode, but the disclosure is not limited thereto. For example, the light-emitting element OLED may be a micro LED element, a nano LED element, the like, or a combination thereof.

The light-emitting element OLED may include a third anode AE3, a hole control layer HCL, a light-emitting layer EML, an electron control layer ECL, and a cathode CE. Although FIG. 3 schematically illustrates the light-emitting element OLED including the third anode AE3, the disclosure is not limited thereto, and the light-emitting element OLED may include one of a first anode AE1, a second anode AE2, and a third anode AE3. The first to third anodes AE1, AE2, and AE3 may be provided separately for each pixel PX (see, e.g., FIG. 1A).

The first anode AE1 may be disposed to correspond to the first light-emitting region PXA-B, the second anode AE2 may be disposed to correspond to the second light-emitting region PXA-R, and the third anode AE3 may be disposed to correspond to the third light-emitting region PXA-G. An expression “An element corresponds to another element” may mean that two elements overlap each other in a plan view of the display panel DP and may not be limited to having a same area.

The first to third anodes AE1, AE2, and AE3 may be disposed on the fourth insulating layer IL4. Each of the first to third anodes AE1, AE2, and AE3 may be directly or indirectly electrically connected to a corresponding driving transistor (e.g., the driving transistor T-D). For example, the third anode AE3 may be directly or indirectly connected to the driving transistor T-D illustrated in FIG. 3.

The pixel defining film PDL may be disposed on the fourth insulating layer IL4. The pixel defining film PDL may be an organic layer. The pixel defining film PDL may expose a portion of each of the first to third anodes AE1, AE2, and AE3. For example, a pixel defining film opening PDL-OP may be defined in the pixel defining film PDL. A portion of each of the first to third anodes AE1, AE2, and AE3 may be exposed through the pixel defining film opening PDL-OP.

Each of a first region EA1, a second region EA2, and a third region EA3 may be defined by the pixel defining film opening PDL-OP. The first region EA1 may correspond to the first light-emitting region PXA-B, the second region EA2 may correspond to the second light-emitting region PXA-R, and the third region EA3 may correspond to the third light-emitting region PXA-G.

The hole control layer HCL, the light-emitting layer EML, the electron control layer ECL, and the cathode CE may be disposed (e.g., commonly or entirely disposed) in the first to third light-emitting regions PXA-B, PXA-R, and PXA-G and the non-light-emitting region NPXA.

The hole control layer HCL may be disposed on the pixel defining film PDL and the first to third anodes AE1, AE2, and AE3. The hole control layer HCL may include a hole transport layer (in addition to a hole injection layer).

The light-emitting layer EML may have a single-layered structure, a tandem structure, or the like. The light-emitting layer EML may generate blue light as source light. The blue light may have a wavelength in a range of about 410 nm (nanometer) to about 480 nm. A light-emitting spectrum of the blue light may have a peak wavelength in a range of about 440 nm to about 460 nm. The light-emitting layer EML may be commonly disposed in the first to third light-emitting regions PXA-B, PXA-R, and PXA-G, or may be independently disposed in each of the first to third light-emitting regions PXA-B, PXA-R, and PXA-G. Being independently disposed may mean that the light-emitting layer EML is separately disposed in each of the first to third light-emitting regions PXA-B, PXA-R, and PXA-G.

The electron control layer ECL may be disposed on the light-emitting layer EML. The electron control layer ECL may include an electron transport layer (in addition to an electron injection layer).

The cathode CE may be disposed on the electron control layer ECL. The cathode CE may be commonly disposed in multiple pixels PX (see, e.g., FIG. 1A).

The thin film encapsulation layer TFE may be disposed on and seal the display element layer EL. For example, the thin film encapsulation layer TFE may be disposed (e.g., disposed directly) on the cathode CE. The thin film encapsulation layer TFE may include a first inorganic encapsulation layer ITL1, an organic encapsulation layer OTL, and a second inorganic encapsulation layer ITL2 which are sequentially stacked.

The first inorganic encapsulation layer ITL1 and the second inorganic encapsulation layer ITL2 may protect the display element layer EL from moisture, oxygen, and/or the like. The first inorganic encapsulation layer ITL1 and the second inorganic encapsulation layer ITL2 may be formed by depositing an inorganic material. For example, the first inorganic encapsulation layer ITL1 and the second inorganic encapsulation layer ITL2 may include at least one of silicon nitride, silicon oxynitride, silicon oxide, titanium oxide, and aluminum oxide.

The organic encapsulation layer OTL may be disposed between the first inorganic encapsulation layer ITL1 and the second inorganic encapsulation layer ITL2. The organic encapsulation layer OTL may protect the display element layer EL from foreign substances such as dust particles or the like. The organic encapsulation layer OTL may be formed by depositing, printing, or coating an organic material. For example, the organic encapsulation layer OTL may include a polymer-based organic layer, for example, an acryl-based organic layer or the like. However, the disclosure is not limited thereto.

FIG. 3 illustrates that the thin film encapsulation layer TFE includes two inorganic layers and one organic layer, but the disclosure is not limited thereto. For example, the thin film encapsulation layer TFE may include three inorganic layers and two organic layers, and the thin film encapsulation layer TFE may have a structure in which the inorganic layers and the organic layers are alternately stacked on each other.

In an embodiment of the disclosure, the display panel DP may further include a refractive index control layer (not illustrated) to improve light emission efficiency on the upper side of the thin film encapsulation layer TFE.

The upper display substrate 200 may be disposed on the lower display substrate 100. The upper display substrate 200 may include a second base substrate BS2, a color filter layer CFL, multiple optical patterns WC1, WC2, and WC3, a partition barrier rib BW, and multiple insulating layers 200-1, 200-2, and 200-3.

The second base substrate BS2 may have a stacked structure of a silicon substrate, a plastic substrate, a glass substrate, an insulating film, the like, or multiple insulating layers. A lower surface BS2-B of the second base substrate BS2 may be flat. The second base substrate BS2 may be a base layer BS2. Multiple light-emitting regions PXA-B, PXA-R, and PXA-G and a non-light-emitting region NPXA may be defined (or divided) in the base layer BS2. The base layer BS2 may be disposed in the light-emitting regions PXA-B, PXA-R, and PXA-G and the non-light-emitting region NPXA.

The color filter layer CFL may be disposed on a surface of the base layer BS2. The color filter layer CFL may include a first color filter CF1, a second color filter CF2, and a third color filter CF3. The first color filter CF1 may be disposed in the first light-emitting region PXA-B, the second color filter CF2 may be disposed in the second light-emitting region PXA-R, and the third color filter CF3 may be disposed in the third light-emitting region PXA-G.

Each of the first to third color filters CF1, CF2, and CF3 may transmit light in a wavelength range (e.g., a specific wavelength range) and may block light outside the wavelength range (e.g., the specific wavelength range). Each of the first to third color filters CF1, CF2, and CF3 may include a base resin and a dye, a pigment, and/or the like dispersed in the base resin. The base resin may be a medium, in which a dye, a pigment, and/or the like is dispersed, and be made of various resin compositions that may be generally referred to as a binder.

The first color filter CF1 may transmit a first color light. The first color light may be source light provided from the light-emitting layer EML. The second color filter CF2 may transmit a second color light. The first color light and the second color light may be different from each other. The third color filter CF3 may transmit a third color light. The first color light, the second color light, and the third color light may be different from each other. For example, the first color light may be blue light, the second color light may be red light, and the third color light may be green light. For example, the first color filter CF1 may be a blue color filter, the second color filter CF2 may be a red color filter, and the third color filter CF3 may be a green color filter. However, the disclosure is not limited thereto. For example, the second color filter CF2 and the third color filter CF3 may be yellow color filters or the like. The second color filter CF2 and the third color filter CF3 may be provided to be connected to each other.

A region in which all of the first to third color filters CF1, CF2, and CF3 overlap each other in a plan view may block light, and the display panel DP may not include a black matrix including a light blocking material. The region in which all of the first to third color filters CF1, CF2, and CF3 overlap each other in a plan view may correspond to the non-light-emitting region NPXA and also correspond to the partition barrier rib BW. An expression “An element corresponds to another element” may mean that two elements overlap each other in a plan view and may not be limited to having a same area.

Multiple first openings OP1 may be defined in the first color filter CF1. Each of the first openings OP1 may overlap at least one of the second color filter CF2 and the third color filter CF3 in a plan view. For example, a (1-1)-th opening OP1-1 and a (1-2)-th opening OP1-2 may be defined in the first color filter CF1. The (1-1)-th opening OP1-1 may overlap the third color filter CF3 among the second color filter CF2 and the third color filter CF3 in a plan view, and the (1-2)-th opening OP1-2 may overlap the second color filter CF2 among the second color filter CF2 and the third color filter CF3 in a plan view.

Multiple second openings OP2 may be defined in the second color filter CF2. Each of the second openings OP2 may overlap at least one of the first color filter CF1 and the third color filter CF3 in a plan view. For example, a (2-1)-th opening OP2-1 and a (2-2)-th opening OP2-2 may be defined in the second color filter CF2. The (2-1)-th opening OP2-1 may overlap the third color filter CF3 among the first color filter CF1 and the third color filter CF3 in a plan view, and the (2-2)-th opening OP2-2 may overlap the first color filter CF1 among the first color filter CF1 and the third color filter CF3 in a plan view.

Multiple third openings OP3 may be defined in the third color filter CF3. Each of the third openings OP3 may overlap at least one of the first color filter CF1 and the second color filter CF2 in a plan view. For example, a (3-1)-th opening OP3-1 and a (3-2)-th opening OP3-2 may be defined in the third color filter CF3. The (3-1)-th opening OP3-1 may overlap the first color filter CF1 among the first color filter CF1 and the second color filter CF2 in a plan view, and the (3-2)-th opening OP3-2 may overlap the second color filter CF2 among the first color filter CF1 and the second color filter CF2 in a plan view.

A measurement opening OP-M may be further defined in the third color filter CF3. The measurement opening OP-M may be a pattern for measuring a position to form the third color filter CF3 before forming the third color filter CF3. The measurement opening OP-M may be defined in the non-light-emitting region NPXA. For example, the measurement opening OP-M may overlap the first color filter CF1 and the second color filter CF2 in a plan view.

Referring to FIGS. 2 and 3, a size of the measurement opening OP-M may be smaller than a size of each of the first to third light-emitting regions PXA-B, PXA-R, and PXA-G. For example, the size of the measurement opening OP-M may be smaller than the size of the first light-emitting region PXA-B, the size of the measurement opening OP-M may be smaller than the size of the second light-emitting region PXA-R, and the size of the measurement opening OP-M may be smaller than the size of the third light-emitting region PXA-G. According to the disclosure, the size of the measurement opening OP-M may be a minimum size within a measurable range. As the size of the measurement opening OP-M is formed to be small, an amount of the third color light passing through the third color filter CF3 may decrease, preventing a reflectance of the display panel DP (see, e.g., FIG. 1A) from increasing.

The measurement opening OP-M may have a polygonal shape. The measurement opening OP-M may have a shape surrounded by n (n is a natural number of 3 or more) or more lines in a plan view. A measurement device may perform a measurement by detecting an edge of the measurement opening OP-M. FIG. 2 illustrates the measurement opening OP-M having a tetragonal shape in a plan view, but the disclosure is not limited thereto.

The measurement opening OP-M may be disposed in the non-light-emitting region NPXA. FIG. 2 illustrates one measurement opening OP-M formed between two third color filters CF3, but the disclosure is not limited thereto. For example, the measurement opening OP-M may be formed between the first color filter CF1 and the second color filter CF2, between the first color filter CF1 and the third color filter CF3, or between the second color filter CF2 and the third color filter CF3. The display device DD may include multiple measurement openings OP-M in the non-light-emitting region NPXA. The measurement opening OP-M according to the disclosure may be formed in various shapes, numbers, and arrangements in the non-light-emitting region NPXA in a plan view.

Referring again to FIG. 3, a first insulating layer 200-1 may be disposed below and cover the first color filter CF1, the second color filter CF2, and the third color filter CF3. A second insulating layer 200-2 may cover the first insulating layer 200-1 and provide a flat surface on the lower side of the second insulating layer 200-2. The first insulating layer 200-1 may be an inorganic film, and the second insulating layer 200-2 may be an organic film.

The partition barrier rib BW may be disposed on a surface of the color filter layer CFL. The partition barrier rib BW may be disposed below the second insulating layer 200-2. The partition barrier rib BW may be disposed in the non-light-emitting region NPXA. Multiple partition openings BW-OP may be defined in the partition barrier rib BW. The partition openings BW-OP may be respectively disposed in the first to third light-emitting regions PXA-B, PXA-R, and PXA-G, and the partition openings BW-OP may be respectively disposed in the first to third regions EA1, EA2, and EA3.

The partition barrier rib BW may include a material having a transmittance lower than or equal to a value (e.g., a predetermined or selectable value). For example, the partition barrier rib BW may include a light-blocking material, for example, a general black agent or the like. The partition barrier rib BW may include a black dye, a black pigment, or the like which is mixed with a base resin. For example, the partition barrier rib BW may include at least one of propylene glycol methyl ether acetate, 3-methoxy-n-butyl acetate, acrylate monomer, acrylic monomer, organic pigment, and acrylate ester. The upper surface BW-U of the partition barrier rib BW may face an upper surface 100-U of the lower display substrate 100.

Multiple optical patterns WC1, WC2, and WC3 may be disposed in the partition openings BW-OP. The optical patterns WC1, WC2, and WC3 may include a first optical pattern WC1, a second optical pattern WC2, and a third optical pattern WC3. Each of the first optical pattern WC1, the second optical pattern WC2, and the third optical pattern WC3 may be formed through an inkjet process or the like. Compositions may be provided in a space defined by the partition barrier rib BW, for example, in each of the partition openings BW-OP to form the first optical pattern WC1, the second optical pattern WC2, and the third optical pattern WC3.

The first optical pattern WC1 may be disposed in the first light-emitting region PXA-B, the second optical pattern WC2 may be disposed in the second light-emitting region PXA-R, and the third optical pattern WC3 may be disposed in the third light-emitting region PXA-G.

The first optical pattern WC1 may transmit source light, the second optical pattern WC2 may convert the source light into the second color light, and the third optical pattern WC3 may convert the source light into the third color light. Each of the first and second optical patterns WC1 and WC2 may include a base resin, quantum dots, scattering particles, and the like, and the third optical pattern WC3 may include a base resin, scattering particles, and the like. In an embodiment of the disclosure, the scattering particles may be omitted from at least one of the first optical pattern WC1, the second optical pattern WC2, and the third optical pattern WC3.

The base resin may be a medium, in which quantum dots or scattering particles are dispersed, and may be made of various resin compositions that may be generally referred to as a binder. Without being limited thereto, however, in this specification, any medium dispersing and disposing quantum dots may be referred to as a base resin regardless of its name, additional functions, constituent materials, and the like. The base resin may be a polymer resin or the like. For example, the base resin may be an acrylic-based resin, a urethane-based resin, a silicone-based resin, an epoxy-based resin, the like, or a combination thereof. The base resin may be a transparent resin or the like.

The scattering particles may be titanium oxide (TiO₂) or silica-based nanoparticles. The scattering particles may increase an amount of light to be provided to an outside by scattering incident light. In an embodiment of the disclosure, at least one of the second optical pattern WC2 and the third optical pattern WC3 may not include the scattering particles.

A quantum dot may be a particle that converts a wavelength of incident light. The quantum dot may have a crystal structure of several nanometers, may include hundreds to thousands of atoms, and may exhibit a quantum confinement effect in which an energy band gap increases due to the small size of the quantum dot. In case that light of a wavelength higher in energy than the band gap is incident on the quantum dots, the quantum dot may absorb the light, may become an excited state, and may fall to a ground state while emitting light of a wavelength (e.g., a specific wavelength). The emitted light of the specific wavelength may have a value corresponding to the band gap. By adjusting a size and a composition of the quantum dot, luminescence characteristics due to the quantum confinement effect may be controlled.

A core of each of the quantum dots may be selected from a Group II-VI compound, a Group III-VI compound, a Group I-III-VI compound, a Group III-V compound, a Group III-II-V compound, a Group IV-VI compound, a Group IV element, a Group IV compound, and a combination thereof.

The Group II-VI compound may be selected from the group consisting of: a binary compound such as CdSe, CdTe, CdS, ZnS, ZnSe, ZnTe, ZnO, HgS, HgSe, HgTe, MgSe, MgS, and a mixture thereof; a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgZnTe, HgZnS, HgZnSe, HgZnTe, MgZnS, MgZnS, and a mixture thereof; and a quaternary compound such as HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

The Group III-VI compound may include a binary compound such as In₂S₃ and In₂Se₃, a ternary compound such as InGaS ₃and InGaSe₃, the like, or a combination thereof.

The Group I-III-VI compound may be selected from the group consisting of: a ternary compound such as AgInS, AgInS₂, CuInS, CuInS₂, AgGaS₂, CuGaS ₂CuGaO₂, AgGaO₂, AgAlO₂, and a mixture thereof; and a quaternary compound such as AgInGaS₂, CuInGaS₂, and a mixture thereof.

The Group III-V compound may be selected from the group consisting of: a binary compound such as GaN, GaP, GaAs, GaSb, AlN, AlP, AlAs, AlSb, InN, InP, InAs, InSb, and a mixture thereof; a ternary compound such as GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof; and a quaternary compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. The Group III-V compound may further include a Group II metal. For example, InZnP or the like may be selected as the Group III-II-V compound.

The Group IV-VI compound may be selected from the group consisting of: a binary compound such as SnS, SnSe, SnTe, PbS, PbSe, PbTe, and a mixture thereof; a ternary compound such as SnSeS, SnSeTe, SnSTe, PbSeS, PbSeTe, PbSTe, SnPbS, SnPbSe, SnPbTe, and a mixture thereof; and a quaternary compound such as SnPbSSe, SnPbSeTe, SnPbSTe, and a mixture thereof. The Group IV element may be selected from the group consisting of Si, Ge, the like, and a mixture thereof. The Group IV compound may be a binary compound such as SiC, SiGe, and a mixture thereof.

The binary compound, the ternary compound, or the quaternary compound may be present in a particle at a uniform concentration, or may be present in a same particle by being divided into states in which concentration distributions of the binary compound, the ternary compound, or the quaternary compound are partially different from each other. The quantum dots may have a core/shell structure in which a quantum dot surrounds another quantum dot. The shell may have a concentration gradient in which a concentration of an element present in the shell gradually decreases toward a center.

In embodiments, the quantum dots may have a core-shell structure including a core including a nanocrystal described above and a shell surrounding the core. The shell of the quantum dots may serve as a protective layer for maintaining semiconductor characteristics by preventing a chemical modification of the core and/or as a charging layer for imparting electrophoretic characteristics to the quantum dots. The shell may be single-layered or multi-layered. The shell may have a concentration gradient in which the concentration of an element present in the shell gradually decreases toward the center. For example, the shell of the quantum dots may include a metal or non-metal oxide, a semiconductor compound, the like, or a combination thereof.

For example, the metal or non-metal oxide of the shell may be selected from the group consisting of: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, and a mixture thereof; and a ternary compound such as MgAl₂O₄, CoFe₂O₄, NiFe₂O₄, CoMn₂O₄, and a mixture thereof, but the disclosure is not limited thereto.

For example, the semiconductor compound of the shell may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, the like, or a combination thereof, but the disclosure is not limited thereto.

The quantum dots may have a full width of half maximum (FWHM) of a light-emitting wavelength spectrum of less than or equal to about 45 nm. For example, the quantum dots may have a full width of half maximum (FWHM) of a light-emitting wavelength spectrum of less than or equal to about 40 nm. For example, the quantum dots may have a full width of half maximum (FWHM) of a light-emitting wavelength spectrum of less than or equal to about 30 nm. The quantum dots may improve color purity or color reproducibility in the above range. Since light emitted through the quantum dots is emitted in all directions, a viewing angle of light may be improved.

Shapes of the quantum dots are not particularly limited to shapes generally used in the art, and shapes such as spherical, pyramidal, multi-arm-shaped, cubic nanoparticles, nanotubes, nanowires, nanofibers, and nanoplate-shaped particles, or the like may be used.

The quantum dots may control a color of light emitted according to a particle size, and accordingly, the quantum dots may have various light-emitting colors such as blue, red, green, and the like.

A third insulating layer 200-3 may cover the partition barrier rib BW, the first optical pattern WC1, the second optical pattern WC2, and the third optical pattern WC3. For example, the third insulating layer 200-3 may be an inorganic film that seals the partition barrier rib BW, the first optical pattern WC1, the second optical pattern WC2, and the third optical pattern WC3.

The first color filter CF1 may include a first side surface S-CF1 defining the (1-1)-th opening OP1-1 and the (1-2)-th opening OP1-2, the second color filter CF2 may include a second side surface S-CF2 defining the (2-1)-th opening OP2-1 and the (2-2)-th opening OP2-2, and the third color filter CF3 may include a third side surface S-CF3 defining the (3-1)-th opening OP3-1 and the (3-2)-th opening OP3-2.

After depositing the color filter CF1, CF2, or CF3 (for example, the first color filter CF1, the second color filter CF2, or the third color filter CF3), a region in which the color filter CF1, CF2, or CF3 is to be deposited may be measured by using a measurement device (not illustrated). The measurement device may measure multiple openings of the color filter CF1, CF2, or CF3 by detecting a boundary of the color filter CF1, CF2, or CF3 in a plan view. By using a measurement result, it may be confirmed whether a deposition process of the color filter CF1, CF2, or CF3 has been performed properly. Boundaries of the color filters may be the first to third side surfaces S-CF1, S-CF2, and S-CF3 of the first to third color filters CF1, CF2, and CF3.

For example, after forming the first color filter CF1, the (1-1)-th opening OP1-1 and/or the (1-2)-th opening OP1-2 may be measured by detecting the first side surface S-CF1 of the first color filter CF1. By using a measurement result of the first openings OP1, it may be confirmed whether the first color filter CF1 is deposited at a designed position. After forming the second color filter CF2, the (2-1)-th opening OP2-1 and/or the (2-2)-th opening OP2-2 may be measured by detecting the second side surface S-CF2 of the second color filter CF2. By using a measurement result of the second openings OP2, it may be confirmed whether the second color filter CF2 is deposited at a designed position.

After forming the third color filter CF3, the (3-1)-th opening OP3-1 and/or the (3-2)-th opening OP3-2 may be measured by detecting the third side surface S-CF3 of the third color filter CF3. By using a measurement result of the third openings OP3, it may be confirmed whether the third color filter CF3 is deposited at a designed position. However, as the third side surface S-CF3 is formed adjacent to the first side surface S-CF1 of the first color filter CF1 and the second side surface S-CF2 of the second color filter CF2, a measurement space may be narrow, and measurement of the third color filter CF3 may be unclear.

According to the disclosure, in case that the third color filter CF3 is measured, a side surface of the measurement opening OP-M may be detected instead of the third side S-CF3 of the third color filter CF3. In case that the measurement opening OP-M is detected and measured, an occurrence of erroneous measurement due to the side surfaces S-CF1 and S-CF2 of the previously formed other adjacent color filters CF1 and CF2 may be reduced. Accordingly, a reliability of measurement of the display panel DP may be improved, and the process efficiency of the display panel DP may also be improved.

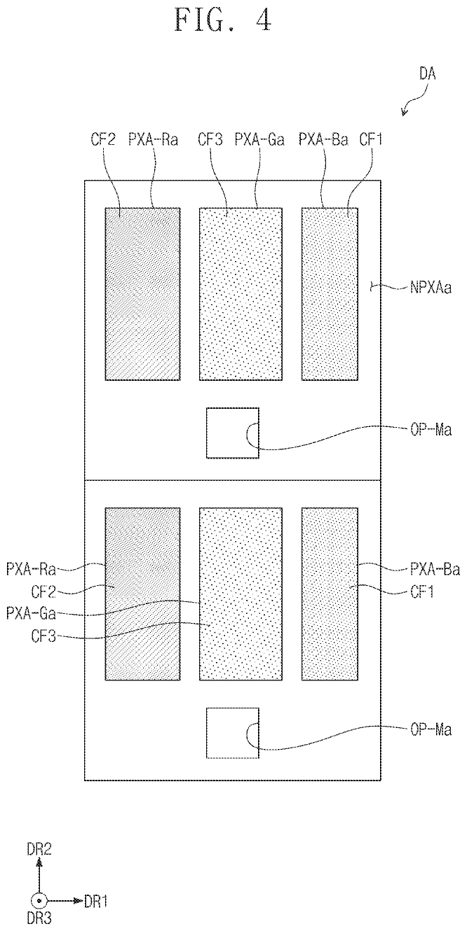

FIG. 4 is a schematic enlarged plan view illustrating a portion of a display area DA of the display panel DP (see, e.g., FIG. 1A) according to an embodiment of the disclosure. FIG. 4 schematically illustrates a flat surface of the display panel DP viewed from the display surface DP-IS (e.g., the display area DA) and schematically illustrates an arrangement of multiple light-emitting regions PXA-Ba, PXA-Ra, and PXA-Ga.

Referring to FIG. 4, the display area DA may include multiple light-emitting regions PXA-Ba, PXA-Ra, and PXA-Ga and a non-light-emitting region NPXAa surrounding the light-emitting regions PXA-Ba, PXA-Ra, and PXA-Ga. The light-emitting regions PXA-Ba, PXA-Ra, and PXA-Ga may include a first light-emitting region PXA-Ba overlapping a portion of the first color filter CF1 in a plan view, a second light-emitting region PXA-Ra overlapping a portion of the second color filter CF2 in a plan view, and a third light-emitting region PXA-Ga overlapping a portion of the third color filter CF3 in a plan view. The first to third light-emitting regions PXA-Ba, PXA-Ra, and PXA-Ga may respectively correspond to regions in which light is emitted from the light-emitting elements OLED (see, e.g., FIG. 3). The first to third light-emitting regions PXA-Ba, PXA-Ra, and PXA-Ga may be classified according to color (e.g., blue color, red color, green color) of light emitted toward an outside of the display panel DP (see, e.g., FIG. 1A).

The first to third light-emitting regions PXA-Ba, PXA-Ra, and PXA-Ga may respectively provide first to third color lights having different colors. For example, the first color light may be blue light, the second color light may be red light, and the third color light may be green light. However, the first to third color lights are not necessarily limited thereto.

The first to third light-emitting regions PXA-Ba, PXA-Ra, and PXA-Ga may be respectively regions in which the first to third color filters CF1, CF2, and CF3 are exposed by the first to third openings OP1, OP2, and OP3 of the first to third color filters CF1, CF2, and CF3 described in FIG. 3.

The non-light-emitting region NPXAa may set boundaries between the first light-emitting region PXA-Ba, the second light-emitting region PXA-Ra, and the third light-emitting region PXA-Ga and may prevent color mixing between the first light-emitting region PXA-Ba, the second light-emitting region PXA-Ra, and the third light-emitting region PXA-Ga. The non-light-emitting region NPXAa may block source light so that the source light is not provided to a user.

The display area DA may include multiple first to third light-emitting regions PXA-Ba, PXA-Ra, and PXA-Ga, and the first to third light-emitting regions PXA-Ba, PXA-Ra, and PXA-Ga may be repeatedly arranged in a pattern (e.g., a predetermined or selectable pattern) in the display area DA. For example, the first to third light-emitting regions PXA-Ba, PXA-Ra, and PXA-Ga may be alternately (or sequentially) arranged in the first direction DR1 to form a ‘third group’. The ‘third group’ may be spaced apart from each other in the second direction DR2. FIG. 4 illustrates only two sets of the first to third light-emitting regions PXA-Ba, PXA-Ra, and PXA-Ga, but the disclosure is not limited thereto.

FIG. 4 schematically illustrates an arrangement form of the first to third light-emitting regions PXA-Ba, PXA-Ra, and PXA-Ga, but the disclosure is not limited thereto. The first to third light-emitting regions PXA-Ba, PXA-Ra, and PXA-Ga may be arranged in various forms. In an embodiment of the disclosure, the first to third light-emitting regions PXA-Ba, PXA-Ra, and PXA-Ga may be arranged in a stripe pattern as illustrated in FIG. 4. In another embodiment, the first to third light-emitting regions PXA-Ba, PXA-Ra, and PXA-Ga may be arranged in a Diamond Pixel™ arrangement or the like.

The first to third light-emitting regions PXA-Ba, PXA-Ra, and PXA-Ga may have various shapes in a plan view. For example, the first to third light-emitting regions PXA-Ba, PXA-Ra, and PXA-Ga may have polygonal, circular, elliptical shapes, the like, or a combination thereof. FIG. 4 illustrates the first to third light-emitting regions PXA-Ba, PXA-Ra, and PXA-Ga having a quadrangular shape (or a rhombus shape) in a plan view, but the disclosure is not limited thereto.

At least some of the first to third light-emitting regions PXA-Ba, PXA-Ra, and PXA-Ga may have different areas in a plan view. In an embodiment of the disclosure, an area of the first light-emitting region PXA-Ba that emits blue light may be smaller than an area of the second light-emitting region PXA-Ra that emits red light and an area of the third light-emitting region PXA-Ga that emits green light, and the area of the third light-emitting region PXA-Ga that emits green light may be greater than an area of the first light-emitting region PXA-Ba that emits blue light and an area of the second light-emitting region PXA-Ra that emits red light. However, a size relationship of the areas between the first light-emitting region PXA-Ba, the second light-emitting region PXA-Ra, and the third light-emitting region PXA-Ga according to the color of emitted light is not limited thereto. and may vary depending on a design of the display module. However, the disclosure is not limited thereto. The first to third light-emitting regions PXA-Ba, PXA-Ra, and PXA-Ga may have a same area as each other in a plan view.

A shape, an area, an arrangement, and/or the like of the first to third light-emitting regions PXA-Ba, PXA-Ra, and PXA-Ga according to the disclosure may be variously designed according to a color of emitted light, a size and a configuration of the display module, or the like. and are not limited to the embodiment illustrated in FIG. 2.

A measurement opening OP-Ma may be defined in the third color filter CF3 in a region overlapping the non-light-emitting region NPXAa in a plan view. The measurement opening OP-Ma may be a pattern for measuring a position to form the third color filter CF3 before forming the third color filter CF3. For example, the measurement opening OP-Ma may overlap the first color filter CF1 and the second color filter CF2 in a plan view.

A size of the measurement opening OP-Ma may be smaller than a size of each of the first to third light-emitting regions PXA-Ba, PXA-Ra, and PXA-Ga. For example, the size of the measurement opening OP-Ma may be smaller than the size of the first light-emitting region PXA-Ba, the size of the measurement opening OP-Ma may be smaller than the size of the second light-emitting region PXA-Ra, and the size of the measurement opening OP-Ma may be smaller than the size of the third light-emitting region PXA-Ga. According to the disclosure, the size of the measurement opening OP-Ma may be a minimum size within a measurable range. As the size of the measurement opening OP-Ma is formed to be small, an amount of third color light passing through the third color filter CF3 may decrease, preventing a reflectance of the display panel DP (see, e.g., FIG. 1A) from increasing.

The measurement opening OP-Ma may have a polygonal shape in a plan view. The measurement opening OP-Ma may have a shape surrounded by n (n is a natural number of 3 or more) or more lines in a plan view. A measurement device may perform a measurement by detecting an edge of the measurement opening OP-Ma. FIG. 4 illustrates the measurement opening OP-Ma having a tetragonal shape in a plan view, but the disclosure is not limited thereto.

Although FIG. 4 illustrates two measurement openings OP-Ma arranged in line with the third color filter CF3 in the second direction DR2, the disclosure is not limited thereto. For example, the measurement opening OP-Ma may be arranged with the first color filter CF1 in the second direction DR2 or may be arranged with the second color filter CF2 in the second direction DR2. Multiple measurement openings OP-Ma may be formed in the non-light-emitting region NPXAa. The measurement opening OP-Ma according to the disclosure may be formed in various shapes, numbers, and arrangements in a region overlapping the non-light-emitting region NPXAa in a plan view.

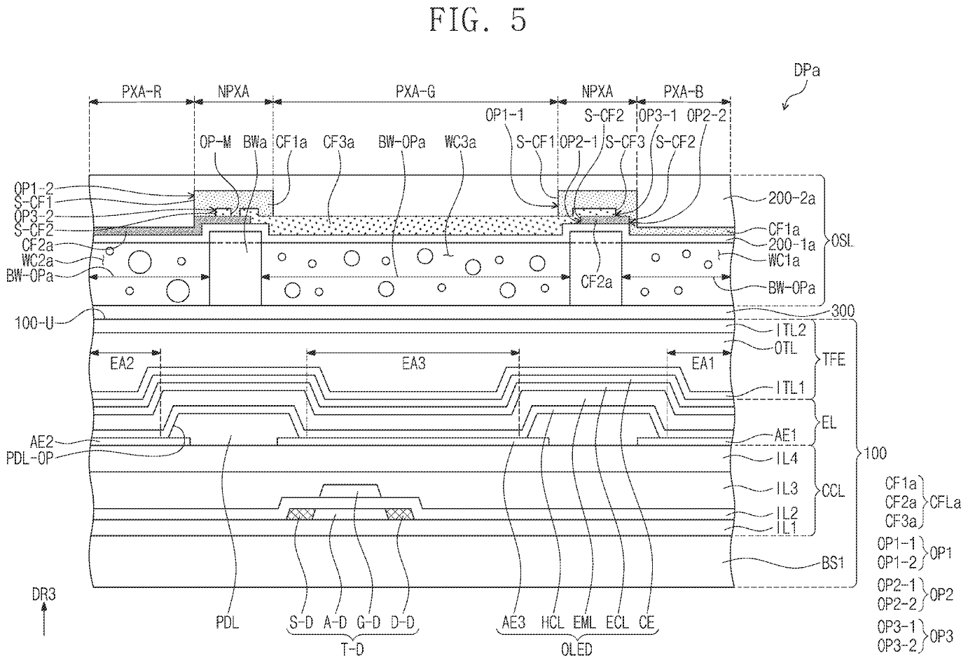

FIG. 5 is a schematic cross-sectional view of a display panel DPa according to an embodiment of the disclosure. FIG. 5 will be described with reference to FIG. 3, and descriptions of same reference numerals will be omitted.

Referring to FIG. 5, the display panel DPa may include a first base substrate BS1, a circuit layer CCL disposed on the first base substrate BS1, a display element layer EL disposed on the circuit layer CCL, a thin film encapsulation layer TFE disposed on the display element layer EL, a functional layer 300 disposed on the thin film encapsulation layer TFE, and a light control layer OSL disposed on the functional layer 300. The first base substrate BS1 may be a base layer BS1.

The functional layer 300 may be formed directly on the lower display substrate 100. An upper surface 100-U of the lower display substrate 100 may be defined by the second inorganic encapsulation layer ITL2. For example, the upper surface 100-U of the lower display substrate may be an upper surface of the second inorganic encapsulation layer ITL2. The upper surface 100-U of the lower display substrate 100 may be flat in the display area DA (see, e.g., FIG. 1A). The functional layer 300 may be formed continuously after a process of forming the second inorganic encapsulation layer ITL2. For example, in a same chamber, the functional layer 300 may be formed continuously after forming the second inorganic encapsulation layer ITL2.

The light control layer OSL may correspond to the upper display substrate 200 described with reference to FIG. 3. A difference between the upper display substrate 200 and the light control layer OSL may be in a manufacturing process. Unlike the upper display substrate 200 (see, e.g., FIG. 3) formed in a process separate from a process of the lower display substrate 100, the light control layer OSL may be formed on the functional layer 300 through a continuous process.

The light control layer OSL may include a partition barrier rib BWa, multiple optical patterns WC1a, WC2a, and WC3a, a color filter layer CFLa, and multiple insulating layers 200-1a and 200-2a.

The partition barrier rib BWa may be disposed on the functional layer 300. The partition barrier rib BWa may be disposed in the non-light-emitting region NPXA. Multiple partition openings BW-OPa may be defined in the partition barrier rib BWa. The partition openings BW-OPa may be each disposed in the first to third light-emitting regions PXA-B, PXA-R, and PXA-G, and the partition openings BW-OPa may be each disposed in the first to third regions EA1, EA2, and EA3.

The optical patterns WC1a, WC2a, and WC3a may be disposed in the partition openings BW-OPa. The optical patterns WC1a, WC2a, and WC3a may include a first optical pattern WC1a, a second optical pattern WC2a, and a third optical pattern WC3a. Each of the first optical pattern WC1a, the second optical pattern WC2a, and the third optical pattern WC3a may be formed through an inkjet process or the like. Compositions may be provided in a space defined by the partition barrier rib BWa, for example, in each of the partition openings BW-OPa to form the first optical pattern WC1a, the second optical pattern WC2a, and the third optical pattern WC3a.

The first optical pattern WC1a may be disposed in the first light-emitting region PXA-B, the second optical pattern WC2a may be disposed in the second light-emitting region PXA-R, and the third optical pattern WC3a may be disposed in the third light-emitting region PXA-G.

A first insulating layer 200-1a may be disposed on and cover the partition barrier rib BWa and the optical patterns WC1a, WC2a, and WC3a.

The color filter layer CFLa may be disposed on the partition barrier rib BWa and the optical patterns WC1a, WC2a, and WC3a. The color filter layer CFLa may be disposed on the first insulating layer 200-1a. The color filter layer CFLa may include a first color filter CF1a, a second color filter CF2a, and a third color filter CF3a. The first color filter CF1a may be disposed in the first light-emitting region PXA-B, the second color filter CF2a may be disposed in the second light-emitting region PXA-R, and the third color filter CF3a may be disposed in the third light-emitting region PXA-G.

The first color filter CF1a may transmit a first color light. The first color light may be source light provided from the light-emitting layer EML. The second color filter CF2a may transmit a second color light. The first color light and the second color light may be different from each other. The third color filter CF3a may transmit a third color light. The first color light, the second color light, and the third color light may be different from each other. For example, the first color light may be blue light, the second color light may be red light, and the third color light may be green light. For example, the first color filter CF1a may be a blue color filter, the second color filter CF2a may be a red color filter, and the third color filter CF3a may be a green color filter. However, the disclosure is not limited thereto.

A region in which all of the first to third color filters CF1a, CF2a, and CF3a overlap each other in a plan view may block light, and the display panel DPa may not include a black matrix including a light blocking material. The region in which all of the first to third color filters CF1a, CF2a, and CF3a overlap each other in a plan view may correspond to the non-light-emitting region NPXA and also correspond to the partition barrier rib BWa.

Multiple first openings OP1 may be defined in the first color filter CF1a, multiple second openings OP2 may be defined in the second color filter CF2a, and multiple third openings OP3 may be defined in the third color filter CF3a.

A measurement opening OP-Ma may be further defined in the third color filter CF3a. The measurement opening OP-Ma may be a pattern for measuring a position in which the third color filter CF3a is to be formed before forming the third color filter CF3a. The measurement opening OP-Ma may be defined in the non-light-emitting region NPXA. For example, the measurement opening OP-Ma may overlap the first color filter CF1a and the second color filter CF2a in a plan view.

A second insulating layer 200-2a may be disposed on and cover the color filter layer CFLa. The second insulating layer 200-2a may be an organic layer, and an inorganic layer may be further disposed below the second insulating layer 200-2a.

After depositing the color filter CF1a, CF2a, or CF3a (for example, the first color filter CF1a, the second color filter CF2a, or the third color filter CF3a), a region in which the color filter CF1a, CF2a, or CF3a is to be deposited may be measured by using a measurement device. The measurement device may measure multiple openings of the color filter CF1a, CF2a, or CF3a by detecting a boundary of the color filter CF1a, CF2a, or CF3a in a plan view. By using a measurement result, it may be confirmed whether the deposition process of the color filter CF1a, CF2a, or CF3a has been performed properly. The boundaries of the color filters may be first to third side surfaces S-CF1, S-CF2, and S-CF3 of the first to third color filters CF1a, CF2a, and CF3a.

For example, after forming the first color filter CF1a, a (1-1)-th opening OP1-1 and/or a (1-2)-th opening OP1-2 may be measured by detecting a first side surface S-CF1 of the first color filter CF1a. By using a measurement result of the first openings OP1, it may be confirmed whether the first color filter CF1a is deposited at a designed position. After forming the second color filter CF2a, a (2-1)-th opening OP2-1 and/or a (2-2)-th opening OP2-2 may be measured by detecting a second side surface S-CF2 of the second color filter CF2a. By using a measurement result of the second openings OP2, it may be confirmed whether the second color filter CF2a is deposited at a designed position.

After forming the third color filter CF3a, a (3-1)-th opening OP3-1 and/or a (3-2)-th opening OP3-2 may be measured by detecting a third side surface S-CF3 of the third color filter CF3a. By using a measurement result of the third openings OP3, it may be confirmed whether the third color filter CF3a is deposited at a designed position. However, as the third side surface S-CF3 is formed adjacent to the first side surface S-CF1 of the first color filter CF1a and the second side surface S-CF2 of the second color filter CF2a, a measurement space may be narrow, and measurement of the third color filter CF3a may be unclear.

According to the disclosure, in case that the third color filter CF3a is measured, a side surface of the measurement opening OP-Ma may be detected instead of the third side S-CF3 of the third color filter CF3a. In case that the measurement opening OP-Ma is detected and measured, an occurrence of erroneous measurement due to the side surfaces S-CF1 and S-CF2 of the previously formed other adjacent color filters CF1a and CF2a may be reduced. Accordingly, a reliability of measurement of the display panel DPa may be improved, and the process efficiency of the display panel DPa may also be improved.

According to the foregoing, for measuring the third color filter CF3 or CF3a, the side surface of the measurement opening OP-M may be detected. In case that the measurement opening OP-M is detected and measured, the occurrence of erroneous measurement due to the side surfaces S-CF1 and S-CF2 of the previously formed other adjacent color filters CF1 and CF2 or CF1a and CF2a may be reduced. Accordingly, the reliability of measurement of the display panel DP or DPa may be improved, and the process efficiency of the display panel DP or DPa may also be improved.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a base layer having a plurality of light-emitting regions and a non-light-emitting region disposed adjacent to the plurality of light-emitting regions; and
a color filter layer disposed on the base layer, wherein
the color filter layer comprises:
a first color filter that transmits a first color light;
a second color filter that transmits a second color light, the first color light and the second color light being different from each other; and
a third color filter that transmits a third color light, the first color light, the second color light, and the third color light being different from each other,
the first to third color filters overlap each other in the non-light-emitting region in a plan view, and
in the third color filter, a measurement opening is defined in a region overlapping the non-light-emitting region in a plan view.

2. The display device of claim 1, wherein the plurality of light-emitting regions comprise:
a first light-emitting region overlapping a portion of the first color filter in a plan view;
a second light-emitting region overlapping a portion of the second color filter in a plan view; and
a third light-emitting region overlapping a portion of the third color filter in a plan view.

3. The display device of claim 2, wherein a size of the measurement opening is smaller than a size of each of the first to third light-emitting regions in a plan view.

4. The display device of claim 1, wherein
the first color light is blue light,
the second color light is red light, and
the third color light is green light.

5. The display device of claim 1, wherein the measurement opening overlaps the first color filter and the second color filter in a plan view.

6. The display device of claim 1, wherein the measurement opening has a polygonal shape in a plan view.

7. The display device of claim 1, further comprising:
a lower display substrate comprising:
a first base substrate;
a plurality of light-emitting elements disposed on the first base substrate; and
a thin film encapsulation layer that covers the plurality of light-emitting elements.

8. The display device of claim 7, further comprising:
a partition barrier rib disposed on the color filter layer and having a plurality of partition openings overlapping the plurality of light-emitting regions in a plan view; and
a plurality of optical patterns disposed in the plurality of partition openings,
wherein an upper surface of the partition barrier rib faces an upper surface of the lower display substrate.

9. The display device of claim 1, further comprising:
a plurality of light-emitting elements disposed on the base layer;
a thin film encapsulation layer that covers the plurality of light-emitting elements;
a partition barrier rib disposed on the thin film encapsulation layer and having a plurality of partition openings overlapping the plurality of light-emitting regions in a plan view; and
a plurality of optical patterns disposed in the plurality of partition openings,
wherein the first to third color filters are disposed on the partition barrier rib and the plurality of optical patterns.

10. The display device of claim 1, wherein
a plurality of first openings are defined in the first color filter, and
each of the plurality of first openings overlaps at least one of the second color filter and the third color filter in a plan view.

11. The display device of claim 1, wherein
a plurality of second openings are defined in the second color filter, and
each of the plurality of second openings overlaps at least one of the first color filter and the third color filter in a plan view.

12. The display device of claim 1, wherein
a plurality of third openings are further defined in the third color filter, and
each of the plurality of third openings overlaps at least one of the first color filter and the second color filter in a plan view.

13. A display device comprising:
a base layer;
a first color filter disposed on the base layer and having a plurality of first openings;
a second color filter disposed on the base layer and having a plurality of second openings; and
a third color filter disposed on the base layer and having a plurality of third openings and a measurement opening, wherein
each of the plurality of first openings overlaps at least one of the second color filter and the third color filter in a plan view;
each of the plurality of second openings overlaps at least one of the first color filter and the third color filter in a plan view;
each of the plurality of third openings overlaps at least one of the first color filter and the second color filter in a plan view; and
the measurement opening overlaps the first color filter and the second color filter in a plan view.

14. The display device of claim 13, wherein
a plurality of light-emitting regions and a non-light-emitting region disposed adjacent to the plurality of light-emitting regions are defined in the base layer; and
the measurement opening overlaps the non-light-emitting region in a plan view.

15. The display device of claim 14, wherein a size of the measurement opening is smaller than a size of each of the plurality of light-emitting regions in a plan view.

16. The display device of claim 13, wherein
the first color filter transmits blue light,
the second color filter transmits red light, and
the third color filter transmits green light.

17. The display device of claim 13, wherein the measurement opening has a polygonal shape in a plan view.

18. The display device of claim 13, further comprising:
a lower display substrate comprising:
a first base substrate;
a plurality of light-emitting elements disposed on the first base substrate; and
a thin film encapsulation layer that covers the plurality of light-emitting elements.

19. The display device of claim 18, further comprising:
a partition barrier rib disposed on the first to third color filters and having a plurality of partition openings overlapping the plurality of light-emitting regions in a plan view; and
a plurality of optical patterns disposed in the plurality of partition openings,
wherein an upper surface of the partition barrier rib faces an upper surface of the lower display substrate.

20. The display device of claim 13, further comprising:
a base substrate;
a plurality of light-emitting elements disposed on the base substrate;
a thin film encapsulation layer that covers the plurality of light-emitting elements;
a partition barrier rib disposed on the thin film encapsulation layer and having a plurality of partition openings overlapping the plurality of light-emitting regions in a plan view; and
a plurality of optical patterns disposed in the plurality of partition openings,
wherein the first to third color filters are disposed on the partition barrier rib and the plurality of optical patterns.
